(19) United States
(12) Patent Application Publication
(10) Pub. No.: US 2014/0144496 A1
(43) Pub. Date: May 29, 2014

(54) PHOTOELECTRIC CONVERSION DEVICE AND METHOD FOR PRODUCING THE SAME

(71) Applicant: FUJITSU LIMITED, Kawasaki-shi (JP)

(72) Inventor: Satoru MOMOSE, Atsugi (JP)

(73) Assignee: FUJITSU LIMITED, Kawasaki-shi (JP)

(21) Appl. No.: 14/170,983

(22) Filed: Feb. 3, 2014

Related U.S. Application Data
(63) Continuation of application No. PCT/JP2011/070499, filed on Sep. 8, 2011.

(51) Int. Cl. H01L 51/42

(52) U.S. Cl. CPC H01L 51/4253; H01L 51/4213
USPC 136/255; 438/82

(57) ABSTRACT

Provided is a photoelectric conversion device which includes a first conductivity type inorganic semiconductor layer, a noble metal film provided partially on the surface of the first conductivity type inorganic semiconductor layer, and a photoelectric conversion layer including a first conductivity type organic semiconductor pillar being in contact with the noble metal film and containing a sulfur atom, and a second conductivity type organic semiconductor pillar being in contact with the first conductivity type inorganic semiconductor layer and including a material not containing a sulfur atom.

### CROSS-REFERENCE TO RELATED APPLICATION

This application is a continuation application of International Application PCT/JP2011/070499, filed on Sep. 8, 2011 and designated the U.S., the entire contents of which are incorporated herein by reference.

### FIELD

The embodiments discussed herein are related to a photoelectric conversion device and a method for producing the same.

### BACKGROUND

An organic thin film type solar cell uses a photoelectric conversion layer combining a p-type organic semiconductor polymer and an n-type organic semiconductor exemplified by fullerene, and is configured to provide charge separation when an exciton produced by incident light arrives at a contact point between the p-type organic semiconductor polymer and the n-type organic semiconductor.

In such an organic thin film type solar cell, a bulk heterojunction type photoelectric conversion layer having an internal structure in which the p-type organic semiconductor material and the n-type organic semiconductor material aggregate with a size of several ten nanometers (nm and are entangled with each other, is frequently used. This is referred to as a bulk heterojunction type organic thin film solar cell.

Such a bulk heterojunction type photoelectric conversion layer is formed by applying a mixed solution, which consists of a p-type organic semiconductor, an n-type organic semiconductor and suitable solvent, and drying the mixed solution. Then, during the course of drying the mixed solution, the p-type organic semiconductor material and the n-type organic semiconductor material respectively spontaneously undergo aggregation and phase, separation, and as a result, a p-n junction with a large specific surface area is formed.

### SUMMARY

According to an aspect of the embodiment, a photoelectric conversion device includes a first conductivity type inorganic semiconductor layer; a noble metal film provided partially on the surface of the first conductivity type inorganic semiconductor layer; and a photoelectric conversion layer including a first conductivity type organic semiconductor pillar being in contact with the noble metal film and containing a sulfur atom, and a second conductivity type organic semiconductor pillar being in contact with the first conductivity type inorganic semiconductor layer and including a material not containing a sulfur atom.

According to another aspect of the embodiment, a method for producing a photoelectric conversion device includes forming a noble metal film partially on the surface of a first conductivity type inorganic semiconductor layer; and applying, on the surface of the first conductivity type inorganic semiconductor layer having the noble metal film formed thereon, a mixed liquid including a first conductivity type organic semiconductor material containing a sulfur atom and a second conductivity type organic semiconductor material not containing a sulfur atom, drying the mixed liquid, and thereby forming a photoelectric conversion layer including a first conductivity type organic semiconductor pillar being in contact with the noble metal film and containing the sulfur atom, and a second conductivity type organic semiconductor pillar being in contact with the first conductivity type inorganic semiconductor layer and including the second conductivity type organic semiconductor material not containing the sulfur atom.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic diagram illustrating the configuration of the photoelectric conversion device according to the present embodiment;

FIG. 2 is a diagram illustrating a cross-sectional image obtained by scanning transmission electron microscopy of a photoelectric conversion device produced by the method for producing a photoelectric conversion device according to the present embodiment;

FIG. 3 is a diagram illustrating a magnified cross-sectional image obtained by scanning transmission electron microscopy of a photoelectric conversion device produced by the method for producing a photoelectric conversion device according to the present embodiment, and the results of an electron energy loss spectroscopic analysis directed to a sulfur atom;

FIG. 4 is an I-V curve of a photoelectric conversion device produced by the method for producing a photoelectric conversion device according to the present embodiment, obtained under white fluorescent lamp light at an illuminance of 380 Lux;

FIG. 5 is an I-V curve of a photoelectric conversion device produced by the method for producing a photoelectric conversion device according to the present embodiment, obtained under a solar simulator under the conditions of AM 1.5;

FIG. 5 is an I-V curve of a comparative example (a device produced without depositing gold, on molybdenum(VI) oxide) against the present embodiment, obtained under white fluorescent lamplight at an illuminance of 380 Lux;

FIG. 7 is an I-V curve of a comparative example (a device produced without depositing gold on molybdenum(VI) oxide) against the present embodiment, obtained under a solar simulator under the conditions of AM 1.5;

FIG. 8 is a schematic diagram illustrating the configuration of a photoelectric conversion device of a modification example of the present embodiment;

FIG. 9 is an I-V curve of a photoelectric conversion device produced by the method for producing a photoelectric conversion device of a modification example of the present embodiment, obtained under white fluorescent lamp light at an illuminance of 380 Lux;

FIG. 10 is an I-V curve of a photoelectric conversion device produced by the method for producing a photoelectric conversion device of a modification example of the present embodiment, obtained under a solar simulator under the conditions of AM 1.5;

FIG. 11 is an I-V curve of a comparative example (a device produced without depositing gold on zinc oxide) against a modification example of the present embodiment, obtained under white fluorescent lamp light at an illuminance of 380 Lux; and

FIG. 12 is an I-V curve of a comparative example (a device produced without depositing gold on zinc oxide) against a modification example of the present embodiment, obtained under a solar simulator under the conditions of AM 1.5.

### DESCRIPTION OF EMBODIMENTS

However, a bulk heterojunction type organic thin film solar cell has a problem that the proportion of the carriers which recombine in the photoelectric conversion layer to the carriers once separated at the p-n junction is high, and the photoelectric conversion efficiency is low. For example, there have been obtained experiment results showing that even if it is attempted to increase the light absorptivity by increasing the thickness of the photoelectric conversion layer, the photoelectric conversion efficiency is rapidly decreased along with an increase in the film thickness.

Furthermore, in order to decrease the probability for the recombination of the carriers, it is effective to increase the carrier transport efficiency in each of the p-type organic semiconductor material and the n-type organic semiconductor material. Therefore, it has been suggested to make the respective materials into a pillar shape that is perpendicular to the surface of the photoelectric conversion layer however, this is only an idea, and there has been no practical means that realizes a photoelectric conversion layer having such a pillar shape.

Thus, it is wished to realize a photoelectric conversion layer in which a p-type organic semiconductor material and an n-type organic semiconductor material are formed in a pillar shape, and to thereby increase the carrier transport efficiency and increase the photoelectric conversion efficiency.

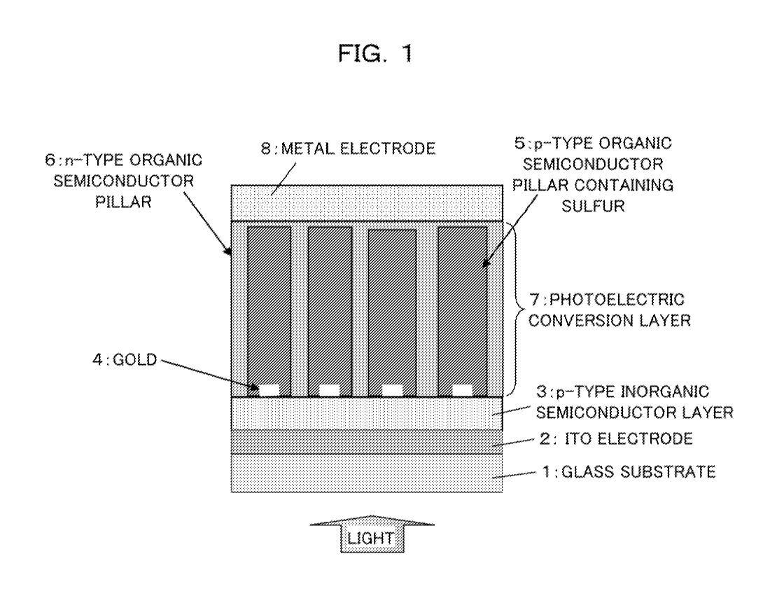

Hereinafter, the photoelectric conversion device according to an embodiment of the present invention and a method for producing the same will be explained based on the drawings, with reference to FIG. 1 to FIG. 7.

The photoelectric conversion device according to the present embodiment is used as, for example, an organic thin film type solar cell, and specifically as a bulk heterojunction type organic thin film solar cell.

This photoelectric conversion device includes, as illustrated in FIG. 1, a substrate 1, a lower electrode 2, a p-type inorganic semiconductor layer 3, a photoelectric conversion layer 7 including a noble metal film 4, a p-type organic semiconductor pillar 5 and an n-type organic semiconductor pillar 6, and an upper electrode 8.

Meanwhile, the p-type inorganic semiconductor layer 3 is also referred to as a first conductivity type inorganic semiconductor layer. Furthermore, the p-type organic semiconductor pillar 5 is also referred to as a first conductivity type organic semiconductor pillar. Furthermore, the n-type organic semiconductor pillar 6 is also referred to as a second conductivity type organic semiconductor pillar. Furthermore, the photoelectric conversion layer 7 is also referred to as a photoelectric conversion film.

Here, the substrate 1 is a transparent substrate that transmits incident light, and the substrate is, for example, a glass substrate.

The lower electrode 2 is a transparent electrode that is provided on the substrate 1 and transmits incident light, and the lower electrode is, for example, an ITO (indium tin oxide) electrode. Here, the lower electrode 2 is a positive electrode.

The p-type inorganic semiconductor layer 3 is a buffer layer that is provided on the lower electrode 2 and functions as a hole transport layer, and the noble metal film 4 is provided partially on the surface of the p-type inorganic semiconductor layer. That is, the buffer layer is the p-type inorganic semiconductor layer 3 having a region whose surface is covered with the noble metal film 4 and a region whose surface is not covered with the noble metal film 4. In addition, the region whose surface is covered with the noble metal film 4 is also referred to as a region in which the noble metal 4 is adherent to the surface. Furthermore, the region whose surface is not covered with the noble metal film 4 is also referred to as a region in which the noble metal 4 is not adherent to the surface.

Furthermore, the p-type inorganic semiconductor layer 3 is, for example, a molybdenum(VI) oxide layer. In addition, the p-type inorganic semiconductor layer 3 may be a layer containing any one material selected from molybdenum(VI) oxide, nickel(II) oxide, copper (I) oxide, vanadium (V) oxide, and tungsten(VI) oxide.

Meanwhile, the buffer layer is constructed by an inorganic semiconductor layer due to the following reason. That is, when an organic semiconductor is used in the buffer layer, depending on the combination of the respective organic semiconductor materials of p-type and n-type used in the photoelectric conversion layer 7, the affinity between the respective both organic semiconductor materials within the photoelectric conversion layer 7 and the material of the buffer layer becomes excessively high, and it is difficult to form a pillar using the noble metal film 4. Therefore, the buffer layer is constructed by an inorganic semiconductor layer herein.

The noble metal film 4 is, for example, a film of gold. In addition, the noble metal film 4 may be a film containing any one material selected from the group consisting of gold, silver, platinum, and palladium.

The photoelectric conversion layer 7 is provided on the p-type inorganic semiconductor layer 3 on the surface of which the noble metal film 4 is provided partially. Here, the photoelectric conversion layer 7 is a bulk heterojunction type photoelectric conversion layer which contains both the p-type organic semiconductor material and the n-type organic semiconductor material, and in which these materials respectively aggregate and form pillar shapes.

The p-type organic semiconductor pillar 5 is a p-type organic semiconductor material having a pillar shape (pillar structure) that is in contact with the noble metal film 4 and extends over the noble metal film 4 and perpendicularly to the surface of the p-type inorganic semiconductor layer 3. That is, the p-type organic semiconductor pillar 5 is a p-type organic semiconductor material naming a pillar shape that is perpendicular to the surface of the photoelectric conversion layer 7.

Furthermore, the p-type organic semiconductor pillar 5 is a p-type organic semiconductor pillar containing a sulfur atom. That is, the p-type organic semiconductor material is a p-type organic semiconductor material containing a sulfur atom, and the material is, for example, poly[N-9′-heptadecanyl-2,7-carbazole-alt-5,5-(4′7′-di-2-thienyl-2′,1′,3′-benzothiadiazole)] (PCDTBT) represented by the following formula (1).

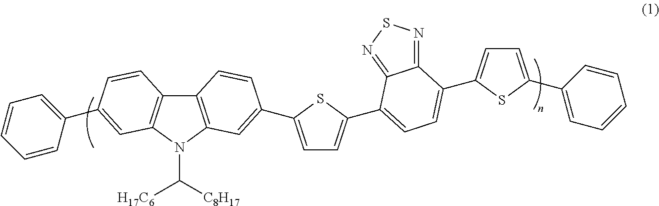

In addition, it is desirable that the p-type organic semiconductor material containing a sulfur atom includes any one material selected from the group consisting of poly-[N-9′-heptadecanyl-2,7-carbazole-alt-5,5-(4′7′-di-2-thienyl-2′,1′,3′-benzothiadiazole)]; poly-3(or 3,4)-alkylthiophene-2,5-diyl (for example, poly[3-hexylthiophene-2,5-diyl](P3HT) represented by the following formula (2)); here, analogous compounds having many side chains or being longer are also included); poly[2,6-(4,4-bis-(2-ethylhexyl)-4H-cyclopenta[2,1-b;3,4-b]-dithiophene)-alt-4,7-(2,1,3-benzothiadiazole)]) (PCPDTBT) represented by the following formula (3); and poly((4,8-bis(octyloxy)benzo(1,2-b:4,5-b′)dithiophene-2,6-diyl)(2-((dodecyloxy)carbonyl)thieno(3,4-b)thiophenediyl)) (PTB1) represented by the following formula (4).

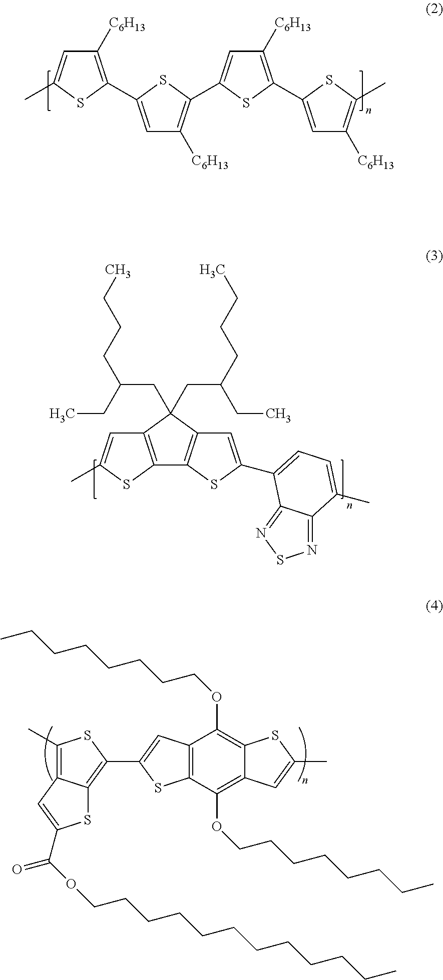

The n-type organic semiconductor pillar 6 is an n-type organic semiconductor material having a pillar shape (pillar structure) that is in contact with the p-type inorganic semiconductor layer 3 and extends over the p-type inorganic semiconductor layer 3 and perpendicularly to the surface of the p-type inorganic semiconductor layer 3. That is, the n-type organic semiconductor pillar 6 is an n-type organic semiconductor material having a pillar shape that is perpendicular to the surface of the photoelectric conversion layer 7.

Furthermore, the n-type organic semiconductor pillar 6 includes an n-type organic semiconductor material that does not contain a sulfur atom. That is, the n-type organic semiconductor material is an n-type organic semiconductor material not containing a sulfur atom, and examples include [6,6]-phenyl-C₇₁-butyric acid methyl ester (PC71BM) and [6,6]-phenyl-C₆₁ butyric acid methyl ester (PC61BM) represented by the following formula (5).

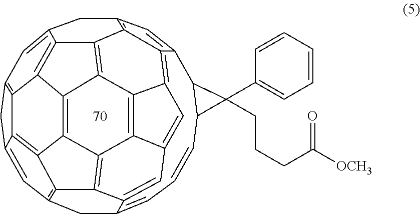 [SMILES: COC(=O)CCCC1(c2ccccc2)C2/C=C\C=C3/Cc4cc5c6c7c(cc8c9c%10c%11c(cc(c%11c%11cc%12cc3c3c4c6c4c3c%12c%11c%10c4c79)C21)C8)C5]

In addition, it is desirable that the n-type organic semiconductor material not containing a sulfur atom includes any one material selected from the group consisting of [6,6]-phenyl-C₇₁-butyric acid methyl ester; [6,5]-phenyl-C₆₁ butyric acid methyl ester; fullerene C60, C70 or C84 represented by the following formula (6); indene-C60 bisadduct (ICBA) represented by the following formula (7); diphenyl-C62-his (butyric acid methyl ester) or diphenyl-C72-bis(butyric acid methyl ester) (C62 (or C72) PCBM-bis) represented by the following formula (8); poly[2-methoxy-5-(2-ethylhexyloxy)-1,4-(1-cyanovinylene-1,4-phenylene)] represented by the following formula (9); and poly[(9,9-dioctyl-2,7-bis{2-cyanovinyienefluorenylene})-alt-co-(2-methoxy-5-{2-ethylhexyloxy}-1,4-phenylene)] represented by the following formula (10).

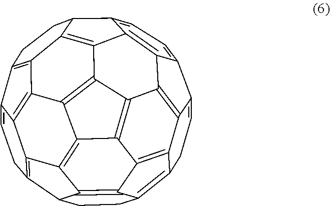 [SMILES: C1=c2c3c4c5c6c7c(ccc8c9c%10c%11c(c%12c%13c%14c%15c(c2c4c2c%15c(c%13%11)c(c62)c%10c87)=C(C1)C%14CC%12)CC=9)C5CC3]

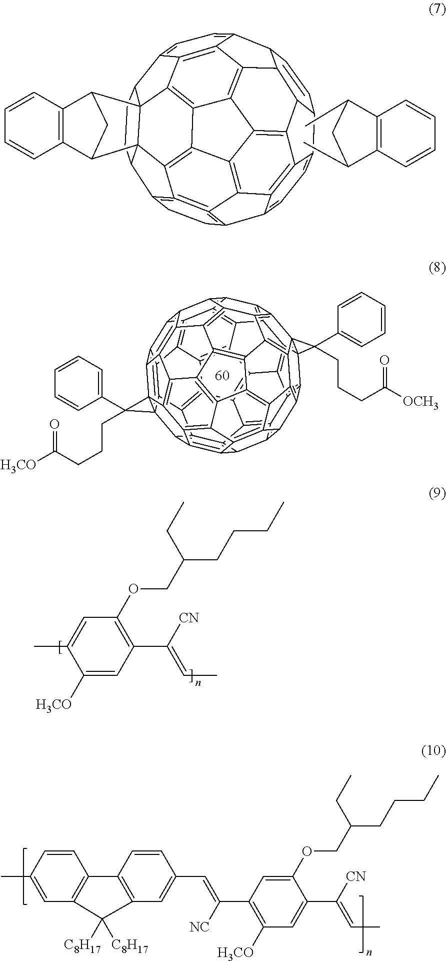

The upper electrode 8 is a metal electrode provided on the photoelectric conversion layer 7, and the upper electrode is, for example, an aluminum electrode. Here, the upper electrode 8 is a negative, electrode.

Next, the method for producing a photoelectric conversion device according to the present embodiment will be described.

First, a lower electrode 2 (transparent electrode) is formed on a substrate 1 (transparent substrate). For example, an ITO electrode 2 having a film thickness of about 200 am is formed over the entire surface of the glass substrate 1.

Next, a p-type inorganic semiconductor layer 3 as a buffer layer is formed on the lower electrode 2. For example, a molybdenum (VI) oxide layer 3 having a film thickness of about 6 nm is formed over the entire surface of the lower electrode 2 by vacuum vapor deposition.

Next, a noble metal film 4 is formed partially on the surface of the p-type inorganic semiconductor layer 3. For example, a gold film 4 (thin film) is formed partially on the surface of the p-type inorganic semiconductor layer 3 by performing vacuum vapor deposition with gold on the p-type inorganic semiconductor layer 3 such that the film thickness (nominal film thickness) of about 0.8 nm. That is, a gold film 4 is formed partially on the surface of the p-type inorganic semiconductor layer 3 such that gold particles are deposited in a state of being dispersed on the surface of the p-type inorganic semiconductor layer 3 by vacuum vapor depositing gold so as to make the film thickness smaller. As such, a gold film is formed on the surface of the p-type inorganic semiconductor layer 3 such that a region covered with the gold film 4 and a region not covered with the gold film 4 both exist. Meanwhile, ideally, it is preferable that the gold film 4 have a square shape having a lengthwise size and a widthwise size equivalent to the exciton diffusion length (for example, about 30 nm) however, for example, any one of the lengthwise size and the widthwise size may be larger than this. Also, it is not necessary for the size and shape of the gold film 4 to be uniform.

Thus, a p-type inorganic semiconductor layer 3 having a noble metal film 4 formed partially on the surface thereof is formed, as a buffer layer, on the lower electrode 2. That is, a p-type inorganic semiconductor layer 3 having a region whose surface is covered with the noble metal film 4 and a region whose surface not covered with the noble metal film. 4 is formed, as a buffer layer, on the lower electrode 2.

Next, a photoelectric conversion layer 7 including a p-type organic semiconductor pillar 5 and an n-type organic semiconductor pillar 6 is formed on the p-type inorganic semiconductor layer 3 on the surface of which the noble metal film 4 is formed.

That is, the photoelectric conversion layer 7 including the n-type organic semiconductor pillar 5 and the n-type organic semiconductor pillar 6 is formed on the surface of the p-type inorganic semiconductor layer 3 having the noble metal film 4 formed thereon, by applying a mixed liquid (mixed solution) including a p-type organic semiconductor material containing a sulfur atom and an n-type organic semiconductor material not containing a sulfur atom, and drying the mixed liquid (mixed solution). For example, the mixed solution includes a p-type organic semiconductor material containing a sulfur atom, an n-type organic semiconductor material not containing a sulfur atom and suitable solvent.

For example, a glass substrate 1 on which up to the buffer layer 3 including the noble metal film 4 have been formed in the manner as described above, is transferred into a glove box filled with nitrogen, and a film of a monochlorobenzene solution (concentration: 2 wt %) containing poly-[N-9′-heptadecanyl-2,7-carbazole-alt-5,5-(4′7′-di-2-thienyl-2′,1′,3′-benzothiadiazole)](PCDTRT) as the p-type organic semiconductor containing a sulfur atom, and [6,6]-phenyl-C₇₁-butyric acid methyl ester (PCBM) as the n-tybe organic semiconductor material not containing a sulfur atom at a weight ratio of 1:3, is formed by spin coating and dried. Thus, the photoelectric conversion layer 7 is formed.

Here, as described above, the noble metal film 4 is formed on the surface of the buffer layer 3 that serves as a foundation layer for forming the photoelectric conversion layer 7, and the p-type organic semiconductor material for forming the photoelectric conversion layer 7 contains a sulfur atom. In this case, since a sulfur atom has a property of forming a strong coordinating bond with a noble metal such as gold, the p-type organic semiconductor material containing a sulfur atom strongly adsorbs to the surface of the noble metal film 4, and using that site as the starting point, the p-type organic semiconductor material aggregates and extends thereover perpendicularly into a pillar shape. In addition, in regard to the phenomenon in which an organic compound containing a sulfur atom adsorbs to a noble metal, please see, for example, Takahiro Iida et al., “Chemical Adsorption of Poly(3-alkylthiophene) on Au Using Self-Assembling Technique”, Japanese Journal of Applied Physics, Vol. 46, No. 46, pp. L1126-L1128 2007), the entire content of which is incorporated herein by reference.

On the other hand, as described above, a p-type inorganic semiconductor layer 3 that serves as a foundation layer for forming the photoelectric conversion layer 7 is formed, and this has a conductivity type different from the n-type organic semiconductor material for forming the photoelectric conversion layer 7 (opposite conductivity type; reverse polarity). In this case, the n-type organic semiconductor material adsorbs to the surface of the p-type inorganic semiconductor layer 3 that is not covered with the noble metal film 4 and is exposed, as a result of an electronic interaction between the n-type organic semiconductor material and the p-type inorganic semiconductor material that is an electron-rich system. Using this site as the starting point, the n-type organic semiconductor material aggregates and extends thereover perpendicularly into a pillar shape.

In this case, since the n-type organic semiconductor material for forming the photoelectric conversion layer 7 does not contain a sulfur atom, the n-type organic semiconductor material does not adsorb to the surface of the noble metal film 4. On the contrary, since the p-type organic semiconductor material for forming the photoelectric conversion layer 7 contains a sulfur atom, the p-type organic semiconductor material is preferentially deposited on the surface of the noble metal film 4. On the other hand, since the n-type organic semiconductor material for forming the photoelectric conversion layer 7 is an electron-deficient system, the n-type organic semiconductor material is preferentially deposited on the p-type inorganic semiconductor material that is an electron-rich system. Therefore, by having the noble metal film 4 formed partially on the surface of the p-type inorganic semiconductor layer 3, the p-type organic semiconductor pillar 5 and the n-type organic semiconductor pillar 6 can be individually produced simply and easily on the p-type inorganic semiconductor layer 3.

In this manner, the p-type organic semiconductor pillar 5 is formed over the noble metal film 4 formed on the surface of the p-type inorganic semiconductor layer 3, and the n-type organic semiconductor pillar 6 is formed over the p-type inorganic semiconductor layer 3, that is, over the surface that is not covered with the noble metal film 4 and is exposed. That is, a photoelectric conversion layer 7 that includes a p-type organic semiconductor pillar 5 being in contact with a noble metal film 4 and containing a sulfur atom, and an n-type organic semiconductor pillar 6 being in contact with the p-type inorganic semiconductor layer 3 and including a material not containing a sulfur atom, is formed.

Thereafter, an upper electrode 8 is formed on the photoelectric conversion layer 7. For example, after the photoelectric conversion layer 7 is formed as described above, an aluminum electrode 8 having a film thickness of about 150 nm is formed by vacuum vapor deposition on the photoelectric conversion layer 7 without performing a heat treatment.

Then, the assembly is encapsulated in, for example, a nitrogen atmosphere, and thus a photoelectric conversion device is completed.

Therefore, according to the photoelectric conversion device according to the present embodiment and the method for producing the same, a photoelectric conversion layer 7 in which a p-type organic semiconductor material and an n-type organic semiconductor material are formed in a pillar shape, can be realized. Thus, there is an advantage that the carrier transport efficiency is increased, and thus the photoelectric conversion efficiency can be increased.

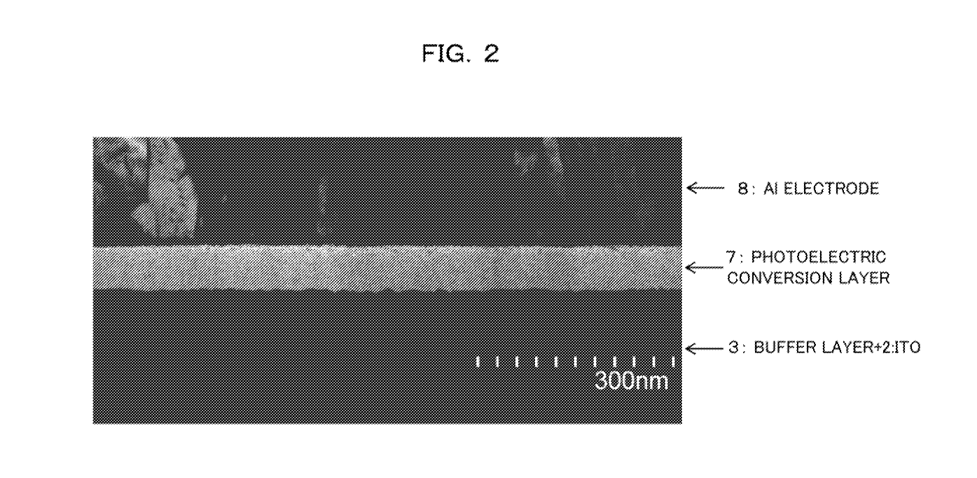

Here, FIG. 2 illustrates the results obtained by observing is cross-section of a photoelectric conversion device produced according to the production method of the embodiment described above by scanning transmission electron microscope (STEM).

In FIG. 2, bright regions and dark regions run in the longitudinal direction inside the photoelectric conversion layer but this is due to the density difference of the organic semiconductor materials, so that PCDTBT having a lower density is illustrated bright, and PCBM having a higher density is illustrated dark. That is, it is illustrated that the p-type organic semiconductor pillar 5 and the n-type organic semiconductor pillar 6 are formed in a direction perpendicular to the surface of the photoelectric conversion layer film surface) in the photoelectric conversion layer 7.

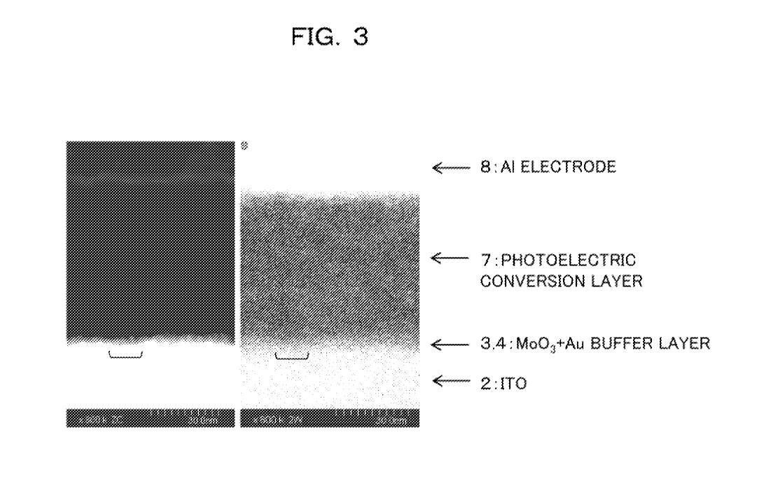

Furthermore, FIG. 3 illustrates the results obtained by observing a cross-section of a photoelectric conversion device produced according to the production method of the embodiment described above, at a higher magnification ratio using STEM and electron energy loss spectroscopy (EELS). Meanwhile, in FIG. 3, the image on the left side is a STEM image, and the image on the right side is an EELS image taken with a sulfur atom as the object of observation.

In FIG. 3, there is a region in which particles having a particle size of about 2 nm to 3 nm are scattered within the gray layer at the upper end of the bright region that is in the lower part of the STEM image on the left side, and this gray layer is made of molybdenum(VI) oxide, while the particles are made of gold. Regarding gold, a film has been formed by performing vacuum vapor deposition such that the nominal film thickness (average film thickness) would be about 0.8 nm; however, since the stage of metal film growth by vapor deposition is only at the stage of three-dimensional growth starting from crystal nuclei, which is an initial stage of the metal film growth by vapor deposition, approximately spherical particles are in a state of being dispersed at the surface of molybdenum(VI) oxide. Meanwhile, although it seems that gold particles are dispersed within the molybdenum(VI) oxide layer, this is because since there are surface asperities having a height of several nanometers on the surface of the molybdenum(VI) oxide layer, the two appear to overlap in the cross-section image. Thus, this does not mean that gold has penetrated into the molybdenum(VI) oxide layer.

In FIG. 3, since the region indicated with a single bracket is a region in which the gold particles 4 on the molybdenum(VI) oxide layer 3 are particularly sparsely scattered (few), the region is illustrated darker than the surrounding molybdenum(VI) oxide layer 3 in the STEM image on the left side. When the relevant site is observed in the EELS image on the right side, it can be seen that, in the photoelectric conversion layer 7 thereon, a region with fewer sulfur atoms (darker than the surroundings) has been formed. Since sulfur atoms are included in PCDTBT, which is a p-type organic semiconductor material, and is not included in PCBM, which is an n-type organic semiconductor material, these results of observation illustrate that a region formed mainly of PCBM is formed in the upper part of the region with a lower density of the gold particles 4 formed on the molybdenum(VI) oxide layer 3, while a region formed mainly of PCDTBT is formed in the upper part of the region with a higher density of the gold particles 4. That is, the pillar shapes illustrated in FIG. 3 are formed as a result of PCBM preferentially aggregating in the region where gold particles 4 are sparse, and PCDTBT preferentially aggregating in the region where gold particles 4 are dense, in accordance with the density (sparse or dense) of the gold particles 4 being adherent on the molybdenum(VI) oxide layer 3.

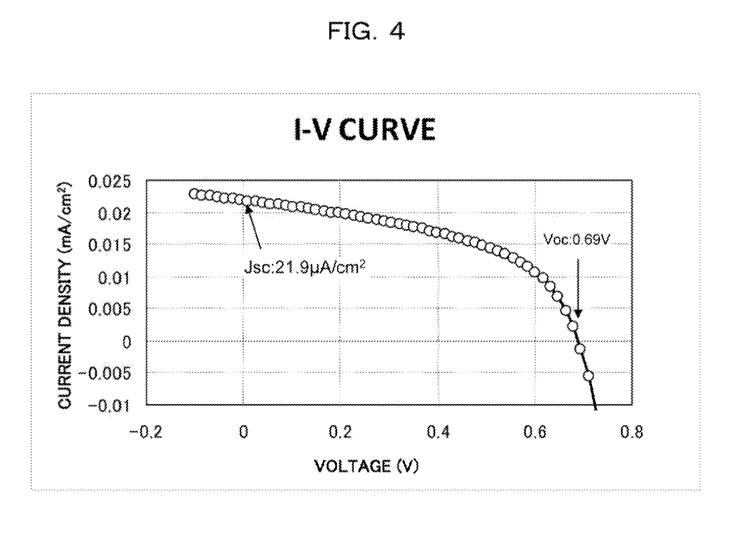

FIG. 4 illustrates an I-V curve of a photoelectric conversion device produced according to the production method of the embodiment described above under white fluorescent lamp light (illuminance: 380 Lux, irradiance: 88.6 μW/cm²).

As illustrated in FIG. 4, the open circuit voltage (Voc) under white fluorescent lamp light (illuminance: 380 Lux, irradiance: 98.6 μW/cm²) was about 0.69 V, the short circuit current density (Jsc) was about 21.9 μA/cm² the fill factor (FF) was about 0.48, the maximum output density (Pmax) was about 7.26 μW/cm² and the photoelectric conversion efficiency was about 8.19%. Meanwhile, the fill factor is defined as (Pmax)/(Voc×Jsc). Furthermore, the photoelectric, conversion efficiency can be determined by the formula: photoelectric conversion efficiency=(Voc×Jsc×FF)/irradiance of incident, light×100(%).

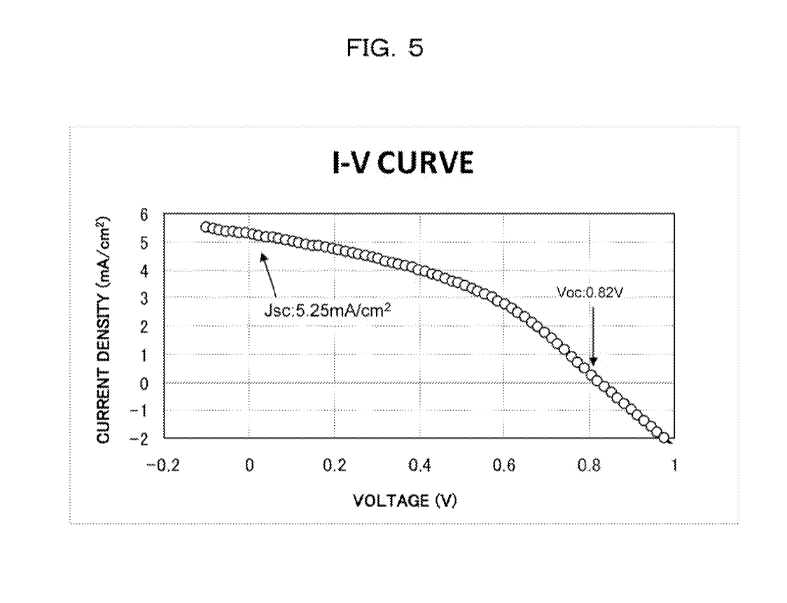

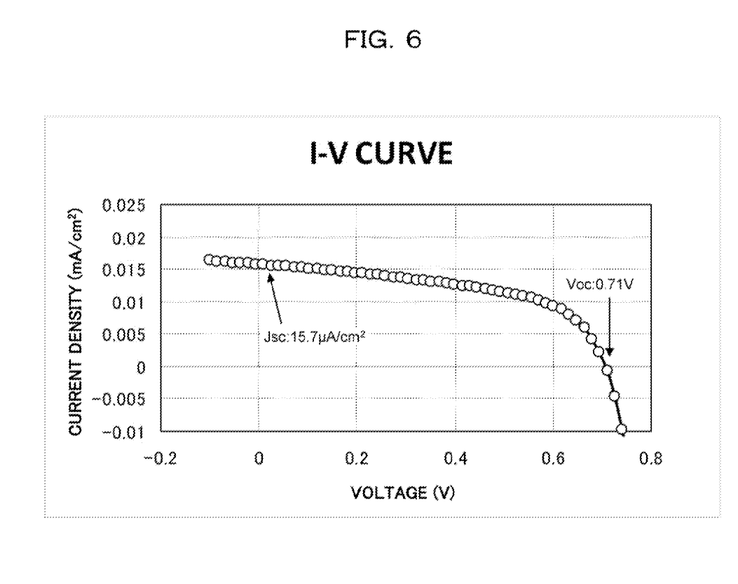

FIG. 5 illustrates an I-V curve, of a photoelectric conversion device produced according to the production method of the embodiment described above under a solar simulator (AM (air mass) 1.5, irradiance: 100 mW/cm²).

As illustrated in FIG. 5, the open circuit voltage (Voc) under a solar simulator (AM 1.5, irradiance: mW/cm²) was about 0.82 V, the short circuit current density (Jsc) was about 5.25 mA/cm², the fill factor (FF) was about 0.40, and the photoelectric conversion efficiency was about 1.72%.

On the contrary, as a Comparative Example, a photoelectric conversion device was produced by the same production method as that of the embodiment described above, except that the gold film 4 was not formed on the surface of the buffer layer 3.

Here, FIG. 6 illustrates an I-V curve, of the photoelectric conversion device of the Comparative Example under white fluorescent lamp light (illuminance; 380 Lux, irradiance: 88.6 μW/cm²).

As illustrated in FIG. 6, under white fluorescent lamp light (illuminance: 380 Lux, irradiance μW/cm²), the open circuit voltage (Voc) was about 0.71 V, the short circuit current density (Jsc) was about 15.7 μA/cm², the fill factor (FF) was about 0.52, and the photoelectric conversion efficiency was about 6.54%.

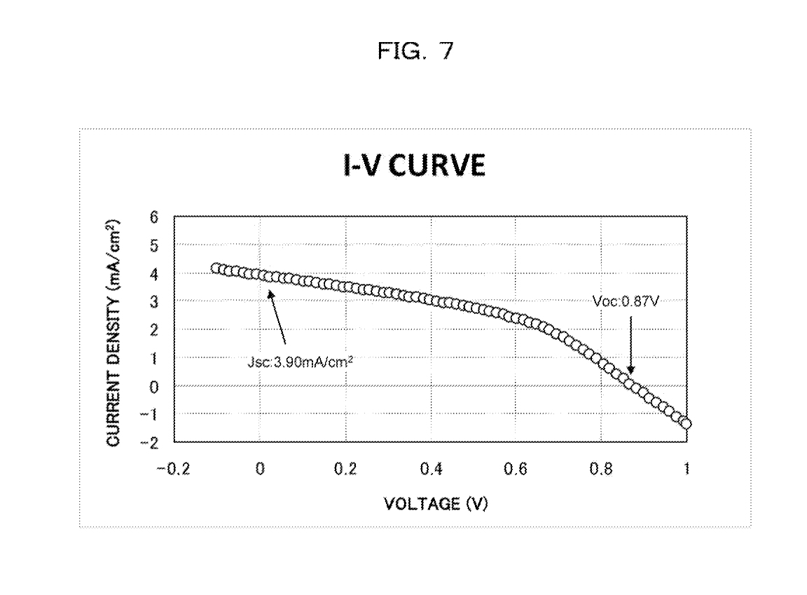

FIG. 7 illustrates an I-V curve of the photoelectric conversion device of the Comparative Example under a solar simulator (AM 1.5, irradiance: 100 mW/cm²).

As illustrated in FIG. 7, under a solar simulator CAM 1.5, irradiance: 100 mW/cm²), the open circuit voltage (Voc) was about 0.87 V, the short circuit current density (Jsc) was about 3.90 mA/cm², the fill factor (FE) was about 0-42, and the photoelectric conversion efficiency was about 1.43%.

As such, it could be confirmed that when a photoelectric conversion device was produced according to the production method of the embodiment described above, a photoelectric conversion layer 7 in which a p-type organic semiconductor material and an n-type organic semiconductor material are formed in a pillar shape, can be realized. In the photoelectric conversion layer 7 having such a pillar structure, since the carrier transport efficiency in the photoelectric conversion layer 7 increases, regarding the photoelectric conversion properties, particularly the short circuit current density (Jsc) increases. As a result, it could be confirmed that an increase in the photoelectric conversion efficiency of about 20% and over is obtained.

Meanwhile, the present invention is not intended to be limited to the configuration described in the embodiment described above, and various modifications can be made to the extent that the gist of the present invention is maintained.

For example, the method for forming a noble metal film 4 partially on the surface of a p-type inorganic semiconductor layer 3 as a buffer layer is not intended to be limited to the specific examples described in connection with the production method of the embodiment described above, and for example, the following two methods may also be used.

In a first method, first, the film thickness (average film thickness) of the gold film 4 that is deposited on the surface of the molybdenum (VI) oxide layer 3 is adjusted to about 5 nm, and the gold film is changed from the microparticle state in the specific examples of the production method of the embodiment described above to a uniform film. Then, the gold film 4 is etched in a checkered pattern composed of lattices that measured about 30 nm×about 30 nm using lithography by EB (electron beam) exposure, and in the regions to be etched, the molybdenum(VI) oxide layer 3 is exposed. Here, the size of the gold film 4 is adjusted to about 30 nm×about 30 nm, which is equivalent to the exciton diffusion length (about 30 nm). In this manner, the gold film 4 may be formed partially on the surface of the molybdenum(VI) oxide layer 3. In this case, despite that the film thickness and surface coverage of the gold film 4 increased, and the amount of light incidence into the photoelectric conversion layer 7 decreased, a photoelectric conversion efficiency equivalent to that of the photoelectric conversion device produced according to the production method of the embodiment described above could be obtained due to the pillar arrangement that was close to ideality.

In a second method, for example, a toluene dispersion liquid of gold nanoparticles having a particle size of about 3 nm to about 5 nm (2 w/v %, manufactured by Sigma-Aldrich Co.) is spin coated on the surface of the molybdenum(VI) oxide layer 3. Next, the system is subjected to a heating treatment at about 150° C. for about 30 minutes. Subsequently, an ozone surface treatment is carried out for about 10 minutes, and thus a clean surface on which gold nanoparticles 4 is adherent is obtained on the surface of the molybdenum(VI) oxide layer 3. In this manner, a gold film 4 may be formed partially on the surface of the molybdenum(VI) oxide layer 3.

Furthermore, for example, in the embodiment described above, a buffer layer is employed as the p-type inorganic semiconductor layer 3, an organic semiconductor pillar containing a sulfur atom is employed as the p-type organic semiconductor pillar 5, and an organic semiconductor pillar including a material not containing a sulfur atom is employed as the n-type organic semiconductor pillar 6. However, the present invention is not intended to be limited to this.

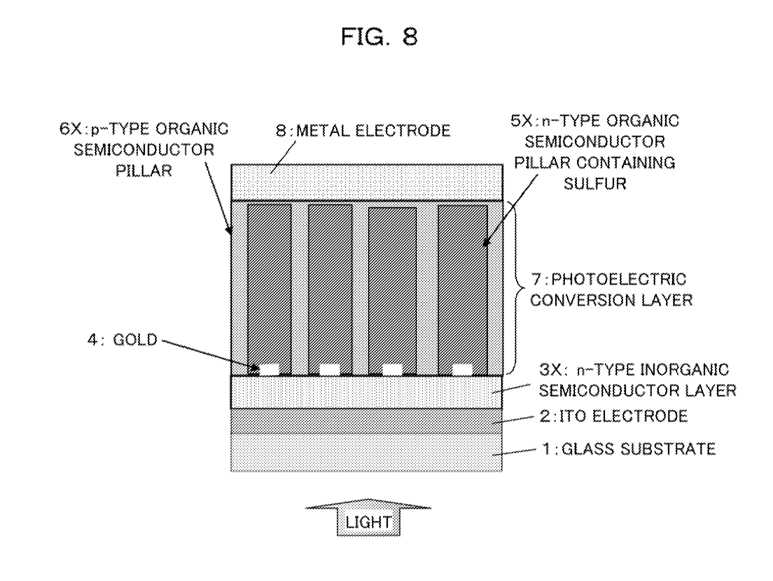

For example, as illustrated in FIG. 8, a buffer layer may be employed as the n-type inorganic semiconductor layer 3X, an organic semiconductor pillar containing a sulfur atom may be employed as the n-type organic semiconductor pillar 5X, and the organic semiconductor pillar including a material not containing a sulfur atom may be employed as the p-type organic semiconductor pillar 6X. Meanwhile, the n-type inorganic semiconductor layer 3X is also called a first conductivity type inorganic semiconductor layer. Furthermore, the n-type organic semiconductor pillar 5X is also called a first conductivity organic semiconductor pillar. Furthermore, the p-type organic semiconductor pillar 6X is also called a second conductivity type organic semiconductor pillar.

in this case, the n-type inorganic semiconductor layer 3X may contain any one material selected from the group consisting of zinc oxide (ZnO), titanium oxide (TiOₓ), aluminum-doped zinc oxide (AZO), and cesium carbonate (CsCO₃). Meanwhile, a ZnO layer, a TiOx layer, and an AZO layer can be formed by, for example, the method described in Hyunchul Oh et al., “Comparison of various sol-gel derived metal oxide layers for inverted organic solar cells”, Solar Energy Materials & Solar Cells, Vol. 95, pp. 2194-2199, 2011, the entire content of which is incorporated herein by reference. A CsCO₃ layer can be formed by, for example, the method described in Hua-Hsien Liao et al., “Highly efficient inverted polymer solar cell by low temperature annealing of Cs₂CO₃ interlayer”, Applied Physics Letters, Vol. 92, 173303, 2008, the entire content of which is incorporated herein by reference.

Furthermore, the n-type organic semiconductor pillar 5X is an n-type organic semiconductor pillar containing a sulfur atom. That is, the n-type organic semiconductor material is an n-type organic semiconductor material containing a sulfur atom, and the n-type organic semiconductor material is, for example, [6,6]-phenyl C61 butyric acid (3-ethylthiophene) ester represented by the following formula (11).

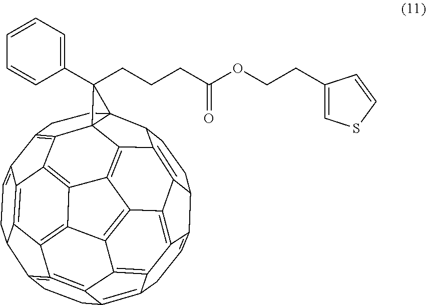

Meanwhile the n-type organic semiconductor material containing a sulfur atom may include any one material selected from the group consisting of [6,6]-phenyl-C61 butyric acid (3-ethylthiophene) ester; [1-(3-methoxycarbonyl)propyl-1-thienyl-6,6-methanofullerene] (ThCBM) represented by the following formula (12); [6,6]-phenyl-C61 butyric, acid (2,5-dibromo-3-ethylthiophene) ester represented by the following formula (13); and poly[(9,9-dioctylfluorenyl-2,7-diyl)-alt-co-(1,4-benzo-[{2,1′,3}-thiadiazole)] (F8BT) represented by the following formula (14).

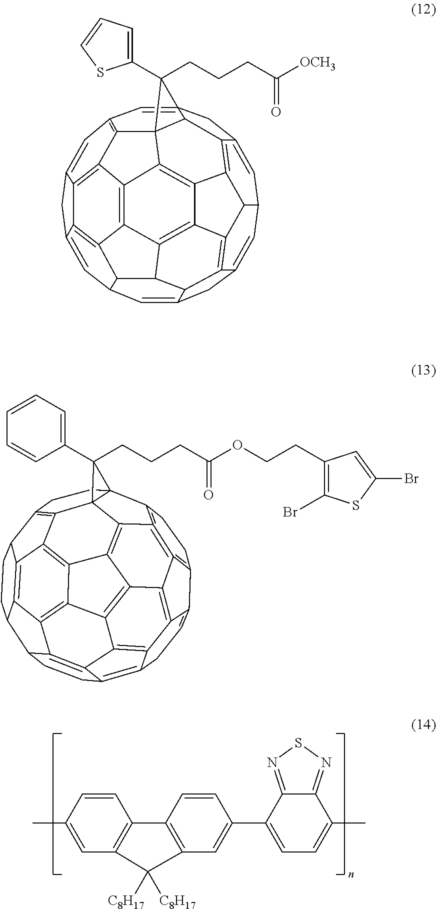

Furthermore, the p-type organic semiconductor pillar 6× includes a p-type organic semiconductor material that does not contain a sulfur atom. That is, the p-type organic semiconductor material is a p-type organic semiconductor material that does not contain a sulfur atom, and an example is poly[[[(2-ethylhexyl)oxy]methoxy-1,4-phenylene)-1,2-ethenediyl] (F2-1-PPV) represented by the following formula (15).

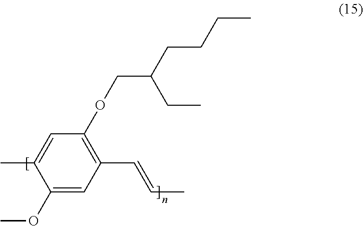 [SMILES: C/C=C/c1cc(OC)c(C)cc1OCC(CC)CCCC]

Meanwhile, the p-type organic semiconductor material that does not contain a sulfur atom may include any one material selected from the group consisting of poly[[[(2-ethylhexyl)oxy]methoxy-1,4-phenylene]-1,2-ethenediyl] (MEH-PPV), and poly(2-methoxy-5-(3′-7′-dimethylootyloxy)-1,4-phenylenevinylene)) (MDMO-PPV) represented by the following formula (16).

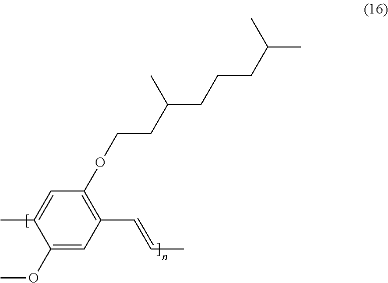 [SMILES: C/C=C/c1cc(OC)c(C)cc1OCCC(C)CCCC(C)C]

In addition, the other configurations and production methods may be designed to be the same as in the case of the embodiment described above, but a specific example of the method for producing a photoelectric conversion device configured as such will be described below.

For example, first, an ITO electrode 2 (lower electrode:transparent electrode) having a film thickness of about 200 nm is formed over the entire surface of a glass substrate 1 (transparent substrate).

Next, a zinc oxide (ZnO) layer having a film thickness of about 30 nm as an n-type organic semiconductor layer 3 is formed over the entire surface of the ITO electrode 2. Here, film formation of the ZnO layer 3 may be carried out according to the method described in, for example, Solar Energy Materials & Solar Cells, vol. 95, pp. 2194, 2011, the entire content of which is incorporated herein by reference, by applying ZnO nanoparticles produced by hydroxylation of zinc acetate with potassium hydroxide.

Subsequently, gold is deposited by vacuum vapor deposition on the n-type inorganic semiconductor layer 3 to a film thickness (nominal film thickness) of about 0.8 nm, and thereby gold film 4 (noble metal film) is formed partially on the surface of the n-type inorganic semiconductor layer 3

in this manner, an n-type inorganic semiconductor layer 3 having a gold film 4 partially on the surface thereof is formed, as a buffer layer, on the ITO electrode 2.

Next, the glass substrate 1 on which up to the buffer layer 3 including the gold film 4 have been formed as described above is transferred to a glove box filled with nitrogen in the inside, and a film of a monochlorobenzene solution (concentration: 2 wt %) containing poly[[[2-ethylhexyloxy]methoxy-1,4-phenylene]-1,2-ethylenediyl] (MEH-PPV) as a p-type organic semiconductor material not containing a sulfur atom and [6,6]-phenyl-C61 butyric acid (2,5-dibromo-3-ethylthiophene) ester as an n-type organic semiconductor material containing a sulfur atom mixed at a weight ratio of 1:3 is formed by spin coating and dried to form a photoelectric conversion layer 7.

Thereby, similarly to the case of the embodiment described above, an n-type organic semiconductor pillar 5X is formed over the gold film 4 formed on the surface of the n-type inorganic semiconductor layer 3X, and a p-type organic semiconductor pillar 5X is formed over the n-type inorganic semiconductor layer 3X, that is, over the surface that is not covered with the gold film 4 and is exposed. That is, a photoelectric conversion layer 7 including the n-type organic semiconductor pillar 5X being in contact with the noble metal film 4 and containing a sulfur atom, and the p-type organic semiconductor pillar 6X being in contact with the n-type inorganic semiconductor layer 3X and including a material not containing a sulfur atom, is formed.

After the photoelectric conversion layer 7 is formed as such, a silver electrode 8 (upper electrode: metal electrode) having a film thickness of about 100 nm is formed on the photoelectric conversion layer 7 by vacuum vapor deposition without performing a heat treatment.

Then, the assembly is encapsulated in, for example, a nitrogen atmosphere, and thus a photoelectric conversion device is completed.

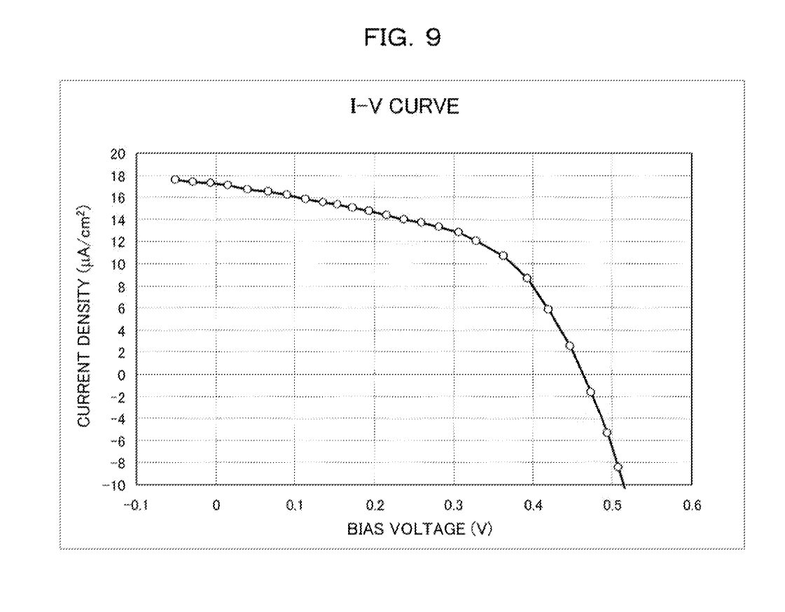

Here, FIG. 9 illustrates an I-V curve of a photoelectric conversion device produced according to such a production method under white fluorescent lamp light (illumination; 380 Lux, irradiance: 88.6 μW/cm²).

As illustrated in FIG. 9, under white fluorescent lamp light (illuminance: 380 Lux, irradiance: 88.6 μW/cm²), the open circuit voltage (Voc) was about 0.46 V, the short circuit current density (Jsc) was about 17.2 μA/cm², the fill factor (FF) was about 0.50, and the photoelectric conversion efficiency was about 4.47%.

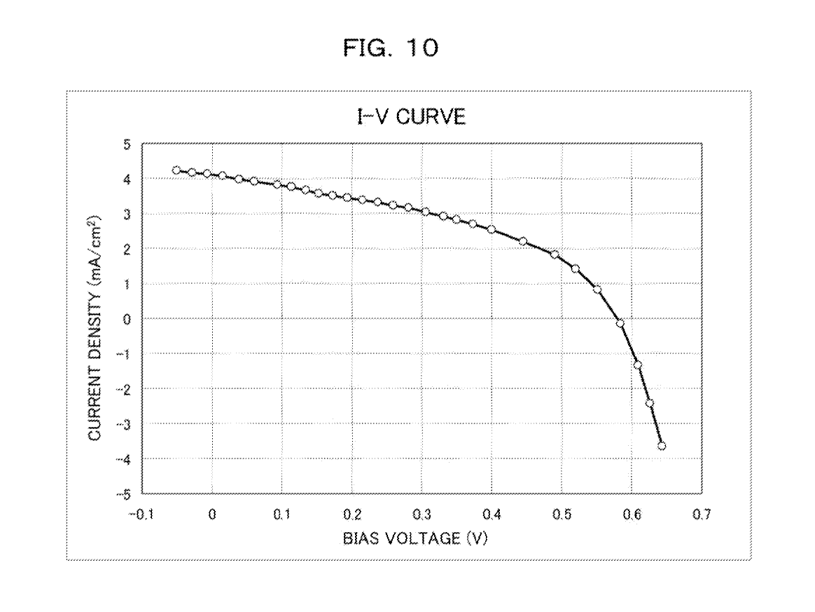

FIG. 10 illustrates an I-V curve of a photoelectric conversion device produced according to the production method described above under a solar simulator (AM 1.5, irradiance: 100 mW/cm²).

As illustrated in FIG. 10, under a solar simulator (AM 1.5, irradiance: 100 mW/cm²), the open circuit voltage (Voc) was about 0.58 V, the short circuit current density (Jsc) was about 4.09 mA/cm², the fill factor (FP) was about 0.42, and the photoelectric conversion efficiency was about 1.00%.

On the contrary, a photoelectric conversion device was produced as a Comparative Example by the same production method as described above, except that the gold film 4 was not formed on the surface of the buffer layer 3.

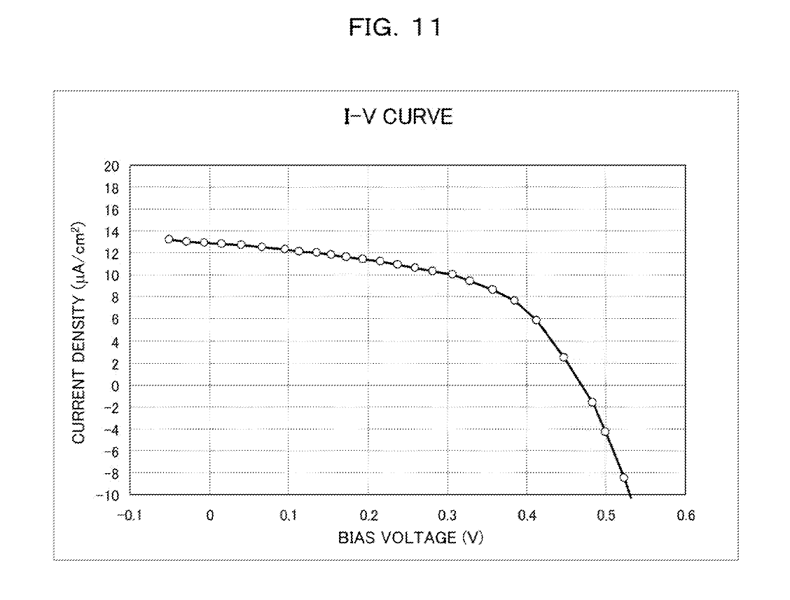

Here, FIG. 11 illustrates an I-V curve of the photoelectric conversion device of the Comparative Example under white fluorescent lamp light (illuminance: 380 Lux, irradiance: 89.6 μW/cm²).

As illustrated in FIG. 11, under white fluorescence lamp light (illuminance: 380 Lux, irradiance: 88.6 μW/cm²), the can circuit voltage (Voc) was about 0.47 V, the short circuit current density (Jsc) was about 12.9 μA/cm², the fill factor (FF) was about 0.51, and the photoelectric conversion efficiency was about 3.49%.

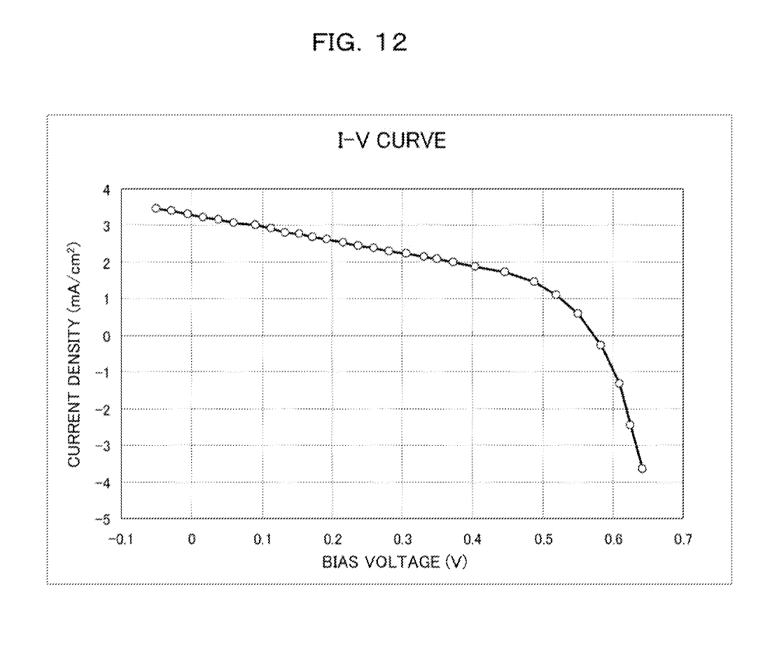

FIG. 12 illustrates an I-V curve of the photoelectric conversion device of Comparative Example under a solar simulator (AM 1.5, irradiance: 100 mW/cm²).

As illustrated in FIG. 12, under a solar simulator (AM 1.5, irradiance: 100 mW/cm²), the open circuit voltage (Voc) was about 0.57 V, the short circuit current density (Jsc) was about 3.29 mA/cm², the fill factor (FF) was about 0.41, and the photoelectric conversion efficiency was about 0.77%.

As such, it could be confirmed that when a photoelectric conversion device is produced according to the production method such as described above, a photoelectric conversion layer 7 in which a p-type organic semiconductor material and an n-type organic semiconductor material are formed in a pillar shape can be realised, and since the carrier transport efficiency within the photoelectric conversion layer 7 is increased, regarding the photoelectric conversion properties, particularly the short circuit current density (Jsc) is increased, so that as a result, an increase in the photoelectric conversion efficiency of about 20% and over can be obtained.

Furthermore, in the embodiment and modification example described above, the case of using the photoelectric conversion device in an organic thin film type solar cell is described as an example, but the use is not limited to this, and the photoelectric conversion device can also be used in, for example, a sensor for an imaging device such as a camera.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A photoelectric conversion device comprising:
a first conductivity type inorganic semiconductor layer;
a noble metal film provided partially on the surface of the first conductivity type inorganic semiconductor layer; and
a photoelectric conversion layer including a first conductivity type organic semiconductor pillar being in contact with the noble metal film and containing a sulfur atom, and a second conductivity type organic semiconductor pillar being in contact with the first conductivity type inorganic semiconductor layer and including a material not containing a sulfur atom.

2. The photoelectric conversion device according to claim 1, wherein the noble metal film includes any one material selected from the group consisting of gold, silver, platinum and palladium.

3. The photoelectric conversion device according to claim 1, wherein the first conductivity type inorganic semiconductor layer is a p-type inorganic semiconductor layer, the first conductivity type organic semiconductor pillar is a p-type organic semiconductor pillar, and the second conductivity type organic semiconductor pillar is an n-type organic semiconductor pillar.

4. The photoelectric conversion device according to claim 3, wherein the p-type inorganic semiconductor layer includes any one material selected from the group consisting of molybdenum(VI) oxide, nickel(II) oxide, copper (I) oxide, vanadium(V) oxide and tungsten(VI) oxide.

5. The photoelectric conversion device according to claim 3, wherein the p-type organic semiconductor pillar includes any one material selected from the group consisting of poly[N-9′-heptadecanyl-2,7-carbazole-alt-5,5-(4′,7′-di-2-thienyl-2,1′,3′-benzothiadiazole)], poly-3(or 3,4)-alkylthiophene-2,5-diyl, poly[2,6-(4,4-bis-(2-ethylhexyl)-4H-cyclopenta[2,1-b;3,4-b]-dithiophene)-alt-4,7-(2,1,3-benzothiadiazole)], and poly((4,8-bis(octyloxy)benzo(1,2-b:4,5-b′)dithiophene-2,6-diyl) (2-((dodecyloxy) carbonyl)thieno(3,4-b)thiophenediyl)).

6. The photoelectric conversion device according to claim 3, wherein the n-type organic semiconductor pillar includes any one material selected from the group consisting of [6,6]-phenyl-C₇₃ butyric acid methyl ester, [6,6]-phenyl-C₆₁ butyric acid methyl ester, fullerene C60, C70 or C84 indene-C60 bisadduct, diphenyl-C62-bis(butyric acid methyl ester), diphenyl-C72-bis(butyric acid methyl ester), poly[2-methoxy-5-(2-ethylhexyloxy)-1,4-(1-cyanovinylene-1,4-phenylene)], and poly[(9,9-dioctyl-2,7-bis{2-cyanovinyienefluorenylene})-alt-co-(2-methoxy-5-{2-ethylhexyloxy}-1,4-phenylene)].

7. The photoelectric conversion device according to claim 1, wherein the first conductivity type inorganic semiconductor layer is an n-type inorganic semiconductor layer, the first conductivity type organic semiconductor pillar is an n-type organic semiconductor pillar, and the second conductivity type organic semiconductor pillar is a p-type organic semiconductor pillar.

8. The photoelectric conversion device according to claim 7, wherein the n-type inorganic semiconductor layer includes any one material selected from the group consisting of zinc oxide, titanium oxide, aluminum-doped zinc oxide, and cesium carbonate.

9. The photoelectric conversion device according to claim 7, wherein the n-type organic semiconductor pillar includes any one material selected from the group consisting of [6,6]-phenyl-C61 butyric acid (3-ethylthiophene) ester, [1-(3-methylcarbonyl)propyl-1-thienyl-6,6-methanofullerene, [6,6]-phenyl-C61 butyric acid (2,5-dibromo-3-ethylthiophene) ester, and poly[(9,9-dioctylfluorenyl-2,7-diyl)-alt-co-(1,4-benzo-{2,1′,3}-thiadiazole)].

10. The photoelectric conversion device according to claim 7, wherein the p-type organic semiconductor pillar includes any one material selected from the group consisting of poly[[[(2-ethylhexyl)oxy]methoxy-1,4-phenylene]-1,2-ethenediyl] and poly(2-methoxy-5-(3′-7′-dimethyloctyloxy)-1,4-phenylenevinylene).

11. A method for producing a photoelectric conversion device, the method comprising:
forming a noble metal film partially on the surface of a first conductivity type inorganic semiconductor layer; and
applying, on the surface of the first conductivity type inorganic semiconductor layer having the noble metal film formed thereon, a mixed liquid including a first conductivity type organic semiconductor material containing a sulfur atom and a second conductivity type organic semiconductor material not containing a sulfur atom, drying the mixed liquid, and thereby forming a photoelectric conversion layer including a first conductivity type organic semiconductor pillar being in contact with the noble metal film and containing the sulfur atom, and a second conductivity type organic semiconductor pillar being in contact with the first conductivity type inorganic semiconductor layer and including the second conductivity type organic semiconductor material not containing the sulfur atom.

12. The method for producing a photoelectric conversion device according to claim 11, wherein the noble metal film includes any one material selected from the group consisting of gold, platinum and palladium.

13. The method for producing a photoelectric conversion device according to claim 11, wherein the first conductivity type inorganic semiconductor layer is a p-type inorganic semiconductor layer, the first conductivity type organic semiconductor pillar is a p-type organic semiconductor pillar, and the second conductivity type organic semiconductor pillar is an n-type organic semiconductor pillar.

14. The method for producing a photoelectric conversion device according to claim 13, wherein the p-type inorganic semiconductor layer includes any one material selected from the group consisting of molybdenum(VI) oxide, nickel (II) oxide, copper(I) oxide, vanadium(V) oxide and tungsten(VI) oxide.

15. The method for producing a photoelectric conversion device according to claim 13, wherein the p-type organic semiconductor pillar includes any one material selected from the group consisting of poly[N-9′-heptadecanyl-2,7-carbazole-alt-5,5-(4′,7′-di-2-thienyl-2′,1′,3′-benzothiadiazole)], poly-3(or 3,4)-alkylthiophene-2,5-diyl, poly[2,6-(4,4-bis-(2-ethylhexyl)-4H-cyclopenta[2,1-b;3,4-b]-dithiophene)-alt-4,7-(2,1,3-benzothiadiazole)], and poly((4,8-bis(octyloxy)benzo(1,2-b:4,5-b′)dithiophene-2,6-diyl)(2-((dodecyloxy)carbonyl)thieno (3,4-b)thiophenediyl)).

16. The method for producing a photoelectric conversion device according to claim 13, wherein the n-type organic semiconductor pillar includes any one material selected from the group consisting of [6,6]-phenyl-C₇₁ butyric acid methyl ester, [6,6]-phenyl-C₆₁ butyric acid methyl ester, fullerene C60, C70 or C84, indene-C60 bisadduct, diphenyl-C62-bis(butyric acid methyl ester), diphenyl-C72-bis(butyric acid methyl ester), poly[2 methoxy-5-(2-ethylhaxyloxy)-1,4-(1-cyanovinylene-1,4-phenylene)], and poly[(9,9-dioctyl-2,7-bis{2-cyanovinylenefluorenylene})-alt-co-(2-methoxy-5-{2-ethylhexyloxy}-1,4-phenylene)].

17. The method for producing a photoelectric conversion device according to claim 11, wherein the first conductivity type inorganic semiconductor layer is an n-type inorganic semiconductor layer, the first conductivity type organic semiconductor pillar is an n-type organic semiconductor pillar, and the second conductivity type organic semiconductor pillar is a p-type organic semiconductor pillar.

18. The method for producing a photoelectric conversion device according to claim 17, wherein the n-type inorganic semiconductor layer includes any one material selected from the group consisting of zinc oxide, titanium oxide, aluminum-doped zinc oxide, and cesium carbonate.

19. The method for producing a photoelectric conversion device according to claim 17, wherein the n-type organic semiconductor pillar includes any one material selected from the group consisting of [6,6]-phenyl-C61 butyric acid (3-ethylthiophene) ester, (1-(3-methylcarbonyl)propyl-1-thienyl-6,6-methanofullerene, [6,6]-phenyl-C61 butyric acid (2,5-dibromo-3-ethylthiophene) ester, and poly[(9,9-dioctylfluorenyl-2,7-diyl)-alt-co-(1,4-benzo-{2,1′3}-thiadiazole)].

20. The method for producing a photoelectric conversion device according to claim 17, wherein the p-type organic semiconductor pillar includes any one material selected from the group consisting of poly[[[(2-ethylhexyl)oxy]methoxy-1,4-phenylene-1,2-ethenediyl] and poly(2-methoxy-5-(3′-7′-dimethyloctyloxy)-1,4-phenylenevinylene).
